(19) United States
(12) Patent Application Publication
(10) Pub. No.: US 2025/0370018 A1
(43) Pub. Date: Dec. 4, 2025

(54) IMPEDANCE MEASUREMENT CIRCUITS AND METHODS FOR OPERATING THE SAME

(71) Applicant: Taiwan Semiconductor Manufacturing Company, Ltd., Hsinchu (TW)

(72) Inventors: Tsung-Che Lu, Hsinchu City (TW); Chin-Ming Fu, Hsinchu City (TW); Chih-Hsien Chang, Hsinchu City (TW)

(73) Assignee: Taiwan Semiconductor Manufacturing Company, Ltd., Hsinchu (TW)

(21) Appl. No.: 18/675,859

(22) Filed: May 28, 2024

(51) Int. Cl. G01R 27/16

(52) U.S. Cl. CPC G01R 27/16

(57) ABSTRACT

An impedance measurement circuit includes a voltage controlled oscillator (VCO) configured to generate an oscillation signal according to a power voltage present on a power rail. The impedance measurement circuit includes an edge sampler coupled to the VCO and configured to generate a first signal sampling the oscillation signal based on a first transition edge of a first sampling clock signal. The impedance measurement circuit includes an accumulator coupled to the edge sampler and configured to accumulate the first signal for generating a second signal based on a third transition edge of a second sampling clock signal. The impedance measurement circuit includes a transition detector configured to generate the second sampling clock signal based on detecting a second transition edge of the first sampling clock signal.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a timing diagram of respective waveforms of a power voltage signal and a sampling clock signal, in accordance with some embodiments.

FIG. 2 illustrates an example circuit diagram of an on-chip system to extract the profile of a power delivery network, in accordance with some embodiments.

FIG. 3 illustrates an example circuit diagram of an impedance measurement circuit, in accordance with some embodiments.

FIG. 4 illustrates waveforms of various signals when operating the impedance measurement circuit of FIG. 3, in accordance with some embodiments.

FIG. 5 illustrates another example circuit diagram of an impedance measurement circuit, in accordance with some embodiments.

FIG. 6 illustrates an example circuit diagram of a transition detector, in accordance with some embodiments.

FIG. 7 illustrates an example circuit diagram of an accumulator, in accordance with some embodiments.

FIG. 8 illustrate a flow chart of an example method for operating an, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with the trend of improving the integration density, high-performance computing (HPC) market has become more popular and being widely used in advanced networking and server applications such as industrial internet of things (IIoT), and engineering applications especially for AI (artificial intelligence) related products that require high data rate, increasing bandwidth and for lowering latency. However, as the package size is getting larger for packages including the HPC component, communication between the dies and power consumption of the HPC circuit has become more challenging issues.

The HPC circuits usually consume large current to perform complicated calculations at high speeds, possess the ability to process large datasets, and generate huge power (or ground) bounce. To minimize development of common-mode currents within the silicon package of large current consuming circuits, a stable power delivery network (PDN) is typically required. Any bounce (noise) on either the power or reference ground may cause simultaneously switching noise or signal integrity problems, as well as electromagnetic interference (EMI). In addition, if power or ground bounce exceeds margin levels, components may not function. Accordingly, to ensure a stable PDN is a critical issue.

Power impedance measurement (PIM) or power monitoring circuits are often utilized to ensure a robust PDN. To assure enough timing margins, in general, one or more digital components (e.g., an accumulator, etc.) of the existing PIM circuits are purposely slowed down (e.g., activated by a purposely decreased frequency). For example, the frequency to drive these digital components may be dropped down to one half of the frequency for testing the PDN. This may disadvantageously increase (e.g., double) testing time. Accordingly, the existing PIM circuits have not been entirely satisfactory in certain aspects.

The present disclosure provides various embodiments of an impedance measurement circuit that can efficiently and accurately describe an equivalent-time sampling (ETS) of a power delivery network (PDN), with much shorter testing time, when compared to the existing PIM circuits. In general, the PDN is configured to provide supply voltage to any of various integrated circuits (ICs). In various embodiments of the present disclosure, the impedance measurement circuit, as disclosed herein, can include an edge sampler and an accumulator that can be activated by respective first and second sampling clock signals with the same frequency, which is further equal to the frequency for testing the PDN (e.g., generating a profile of the PDN). The edge sampler can utilize a rising edge of the first sampling clock signal to sample an oscillation signal generated according to a voltage present on the PDN, and the accumulator can utilize a rising edge of the second sampling clock signal to accumulate the sampled signal for generating measurement results. The disclosed impedance measurement circuit further includes a transition detector. The second sampling signal can be generated by the transition detector based on detecting a falling edge of the first sampling clock signal. The falling edge (of the first sampling clock signal) that pulls up the second sampling clock signal immediately follows the rising edge (of the first sampling clock signal). Stated another way, every time that the edge sampler samples a data point of the oscillation signal, the accumulator can be activated to accumulate the sampled signal within one half of a period of the first sampling clock signal. Accordingly, accuracy of the accumulator can be significantly improved, which advantageously reduce the amount of testing time of disclosed impedance measurement circuit.

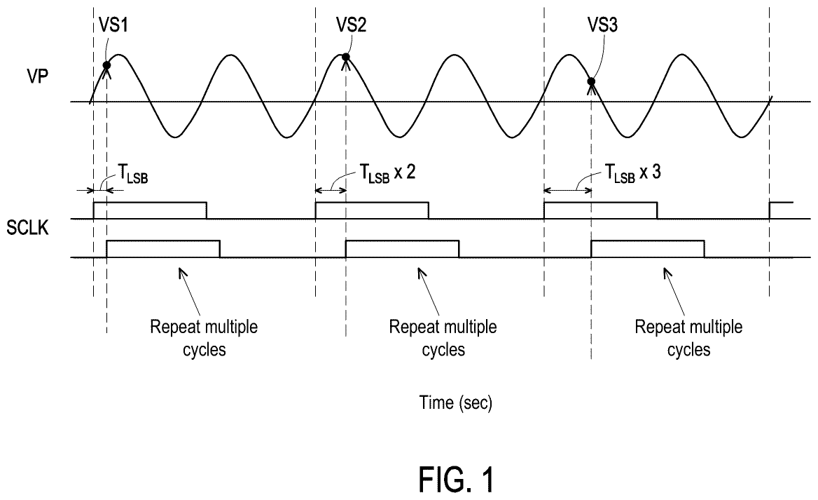

FIG. 1 illustrates a timing diagram of respective waveforms of a power voltage signal and a sampling clock signal, in accordance with some embodiments of the disclosure. It should be noted that the waveforms of FIG. 1 are merely an example, and is not intended to limit the present disclosure.

As shown, a power voltage signal VP, which may be periodic, represents a voltage difference signal of a PDN and a sampling clock signal SCLK is a clock signal which can be used to sample the power voltage signal VP. Points VS1, VS2, and VS3 on the VP waveform may correspond to a first sampling point, a second sampling point, and a third sampling point, respectively. Since a sampling rate of the sampling clock signal SCLK is slower than a frequency of the power voltage signal VP, the sampling clock signal SCLK of lower frequency can be used to sample the power voltage signal VP several times to completely construct the voltage difference signal of the PDN.

A method of equivalent-time sampling (ETS) is typically used to construct an entire waveform of the power voltage signal VP by accumulating the sampling clock signal SCLK over many wave cycles. The power voltage signal VP is sampled over a number of cycles by the sampling clock signal SCLK repetitively. Moreover, a sequential sampling method of ETS can be used to capture an entire waveform and portions of real-time waveforms during multiple trigger events are acquired by introducing a small delay amount (for example, DT1, DT2, and DT3) sequentially. Over time, these portions are assembled into a complete waveform. While using sequential sampling method of ETS, the sampling clock signal SCLK acquires one sampled signal from each trigger event, with a fixed interval delay amount between each acquisition. For example, the delay amount DT1 is 1 times a least significant bit (LSB) of a digital value of a period of the sampling clock signal SCLK, which is sometimes referred to as T_{LSB}. The delay amount DT2 is 2 times the LSB of the digital value of the period of the sampling clock signal SCLK, and the delay amount DT3 is 3 times the LSB of the digital value of the period of the sampling clock signal SCLK. That is, DT1=T_{LSB}, DT2=2×T_{LSB}, and DT3=3×T_{LSB}. The delay amounts DT1, DT2, and DT3 can be variable values.

The sequential sampling method of ETS provides extremely high bandwidths (60 GHz and higher), higher timing resolution needed for telecommunications and device characterization needs, and accuracy as well, especially used for multiple-shot acquisitions and a repetitive waveform. Over time, the instrument accumulates enough sampled signal to reconstruct the waveform. This method guarantees the sample rate of the sampling clock signal SCLK that is slower than the power voltage signal VP to get all the sampling points required to accurately reconstruct the waveform.

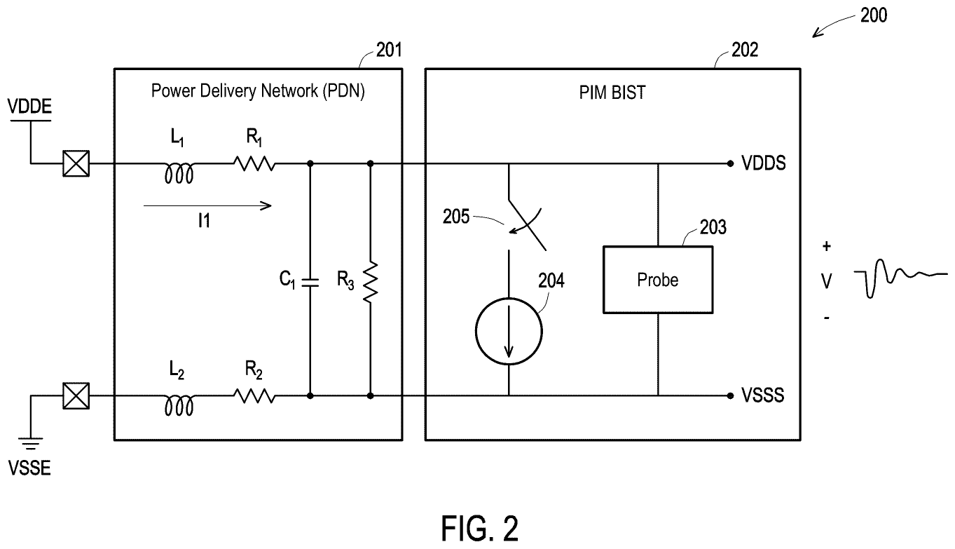

FIG. 2 illustrates an example circuit diagram of a system (e.g., an on-chip circuit) 200 to extract the profile of a PDN, in accordance with some other embodiments of the disclosure. As shown, the on-chip circuit 200 includes a PDN 201 and a PIM built-in self-test (PIM BIST) circuit 202. In some embodiments, the on-chip circuit 200 can be used for both input and output (I/O) power rails.

The PDN 201 is electrically connected to the PIM BIST circuit 202. The PDN 201 and the PIM BIST circuit 202 can be shunt-connected. The PIM BIST circuit 202 may include a probe 203, a current sink 204, and a switch 205. In some embodiments, the current sink 204 and the switch 205 are series-connected. In some embodiments, the probe 203 is shunt connected to one end of the switch 205 and another end of the current sink 204. The PIM BIST circuit 202, which is used to extract the profile of the PDN 201 and test whether the PDN 201 is robust, is frequently used for mass testing. A voltage difference V between two ends of the probe 203 is generated by a difference of the internal power source VDDS and the internal ground source VSSS. In some embodiments, the voltage difference V corresponds to the above-discussed power voltage signal VP. The PDN 201 is used to provide a voltage within regulation limits and with an acceptable noise to each active device.

The PDN 201 may include or be modeled as a capacitance C1, resistors R1-R3, and inductors L1 and L2. The resistor R1 and the inductor L1 are series connected on a first power rail which is connected to an external power source VDDE. The resistor R2 and the inductor L2 are series connected on a second power rail which is connected to an external power source VSSE. The capacitor C1 is coupled between the first power rail and the second power rail, and the resistor R3 is coupled to the capacitor C1 in parallel. The capacitor C1, the resistors R1-R3, and the inductors L1 and L2 may be parasitic components.

The PDN circuit is configured to deliver a power generated by the external power source VDDE and the external ground source VSSE as internal power sources to all devices in an integrated circuit (IC). In general, after a layout of the IC is generated, various subsequent testing steps are typically performed to verify the layout design work. The testing tools simulate the layout design by assuming that the PDN circuit provides a constant voltage source to each circuit component of the IC. During real operations of the IC, each of elements in the IC may be associated with a voltage drop between the power rails. Such the voltage drop may be due to various parasitic components in the PDN circuit, such as the capacitance C1, the resistors R1-R3, and the inductors L1 and L2 may be parasitic components.

In some embodiments, the PDN 201 of the on-chip circuit 200 provides an interconnection framework in which the switch 205 is allowed to control on/off state of the current sink 204. The external power source VDDE of the PDN 201 may be bulky, thus interconnections are used. In some embodiments, the current I1 through components of the PDN 201 creates a direct current (DC) drop and voltage fluctuations. In some embodiments, the PDN 201 is used to regulate voltage for required current to be supplied over time. In some embodiments, the speed or the frequency at which the PDN 201 operates determines the speed or the frequency at which charge can be supplied or removed from capacitors.

The on-chip circuit 200 is configured to measure the power impedance by extracting component profiles of the PDN 201. The current sink 204 is used to produce a step response when the PDN 201 is placed under a load condition. In some embodiments, the current sink 204 may include a fast current loop that detects a current gradually increasing and converging to a step value through a power switch (e.g., the switch 205). After receiving the step response, the voltage difference V between internal power sources VDDS and VSSS (or power voltage signal VP) can be measured by the PIM BIST circuit 202. As such, a model (e.g., profile) of the PDN 201 can be extracted based on the voltage difference V (or power voltage signal VP).

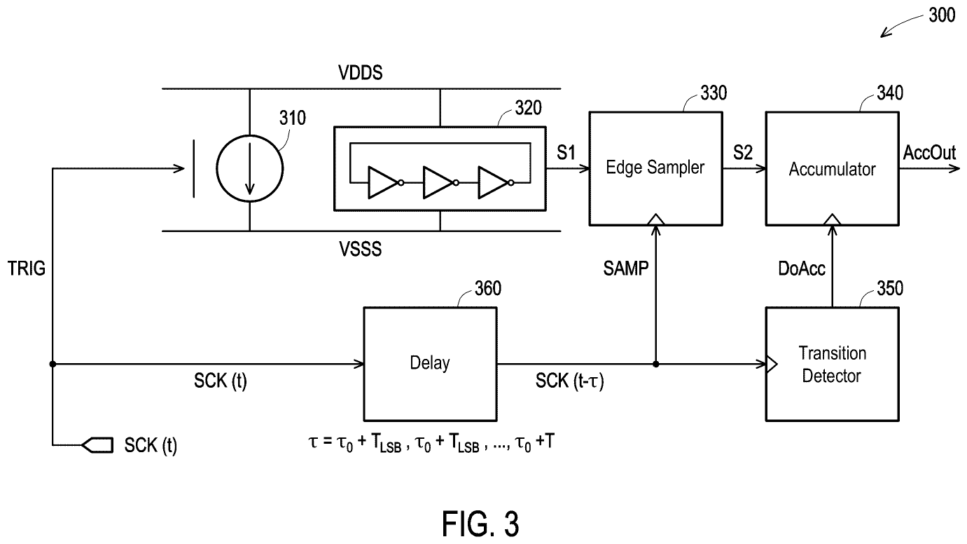

FIG. 3 illustrates an example circuit diagram of an impedance measurement circuit 300, in accordance with various embodiments of the present disclosure. The impedance measurement circuit 300 is configured to perform a time-domain sensing method to measure the power impedance of a PDN, as described above with respect to FIG. 2. For example, the impedance measurement circuit 300 may be an example implementation of the PIM BIST circuit 202. It should be understood that the circuit diagram of FIG. 3 has been simplified, and thus, the impedance measurement circuit 300 can include any of various other components while remaining within the scope of the present disclosure.

As shown, the impedance measurement circuit 300 includes a current source 310, a voltage controlled oscillator (VCO) 320, an edge sampler 330, an accumulator 340, a transition detector 350, and a delay circuit 360. In some embodiments, the edge sampler 330 and the accumulator 340 may be collectively referred to as an operation circuit of the impedance measurement circuit 300. As a brief overview, such an operation circuit of the disclosed impedance measurement circuit 300 can sense a power voltage signal delivered by a PDN based on two sampling clock signals that have the same frequency, so as to generate a measurement result describing a profile of the PDN. The details of the impedance measurement circuit 300 will be described as follows.

The current source 310 is electrically connected to one or more power rails. The power rails can provide an internal (or sensed) power source VDDS and an internal (or sensed) power ground VSSS that are delivered by a corresponding PDN. In some embodiments, the current source 310 can provide a constant electric current flowing between the power rails. The current source 310 can draw a current from the internal power source VDDS to the internal power ground VSSS. Further, the current source 310 can be periodically activated to draw the current according to a trigger signal (hereinafter “TRIG signal”) that is generated based on a global sampling clock signal SCK (hereinafter “SCK signal”). As such, the SCK signal and the TRIG signal can have the same frequency (f_{CLK}/N), where N is an integer and f_{CLK} is inverse to T_{CLK} which is the period of a clock signal (CLK) provided by a clock source.

The edge sampler 330 is electrically coupled to the VCO 320 and the delay circuit 360, and the accumulator 340 is electrically coupled to the edge sampler 330 and the transition detector 350. The VCO 320 can generate an oscillation signal S1 (hereinafter “S1 signal”) based on a variation of a power voltage signal VP (e.g., the voltage difference between the internal power source VDDS and the internal power ground VSSS). The edge sampler 330 can output a signal S2 (hereinafter “S2 signal”) by sampling the S1 signal based on a first sampling clock signal SAMP (hereinafter “SAMP signal”).

In various embodiments of the present disclosure, the SAMP signal can be provided by the delay circuit 360 through delaying the SCK signal with a delay amount, τ. The delay amount τ may correspond to one of the delay amounts DT1, DT2, and DT3 described with respect to FIG. 1. The edge sampler 330 can sample the S1 signal based on a rising edge of the SAMP signal. Stated another way, every time that the edge sampler 330 detects a rising edge of the SAMP signal, the edge sampler 330 can sample one data point of the S1 signal as the S2 signal. The accumulator 340 can receive the S2 signal, and output a signal AccOut (hereinafter “AccOut signal”) selectively accumulating the S2 signal based on a second sampling clock signal DoAcc (hereinafter “DoAcc signal”). The DoAcc signal can be provided by the transition detector 350 based on detecting a falling edge of the SAMP signal. For example, the transition detector 350 can generate one of many pulses of the DoAcc signal, every time that the transition detector 350 detects a falling edge of the SAMP signal. As such, the SAMP signal and the DoAcc signal have the same frequency (e.g., f_{CLK}/N), which is the same as the frequency of the SCK signal. The impedance measurement circuit 300 can output the AccOut signal as a measurement result, which can be utilized to construct the profile of the PDN.

With such a configuration, the accumulation operation can be performed by the accumulator 340 at the same frequency as the SCK signal. For example, the sampling operation can be performed at a rising edge of one of the pulses of a sampling clock signal (e.g., SAMP signal), and immediately after the same pulse falls, the accumulation can be performed. Stated another way, within one period (T) of the sampling clock signal (where T=N/f_{CLK} or N·T_{CLK}), an accumulation following a sampling operation can be performed. Minimum setup and hold margins can be ensured to be equal to N/2·T_{CLK}−T_{Det} and N/2·T_{CLK}+T_{Det}, respectively, where T_{Det} represents a delay amount incurred by the transition detector 350 which may be approximately equal to T_{CLK}. Accordingly, testing time for each data point can be approximated as N·M·T_{CLK}, where M represents M-times accumulation for a statistical outcome.

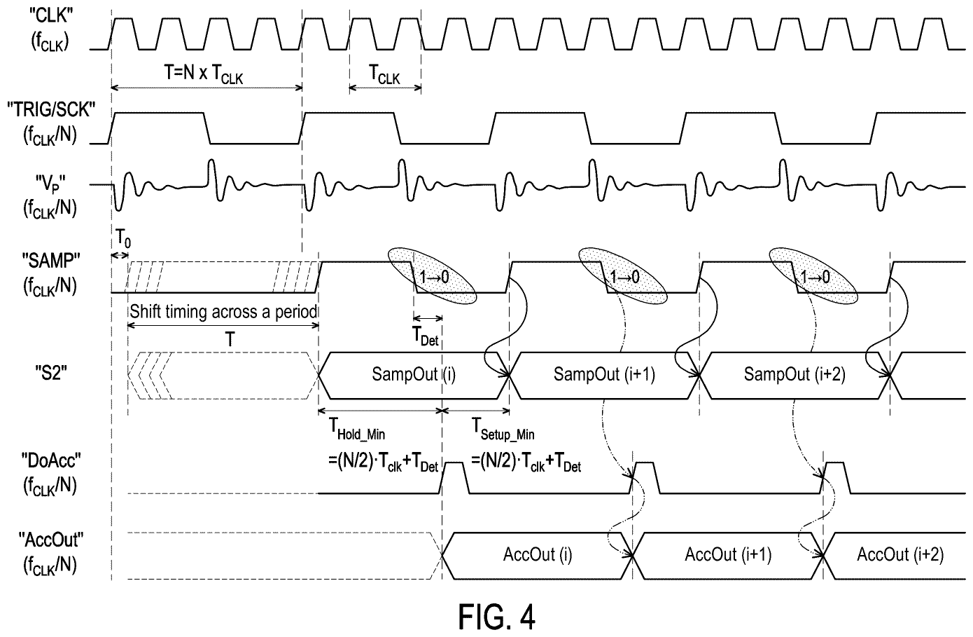

FIG. 4 illustrates example waveforms of various foregoing signals over time when operating the impedance measurement circuit 300, in accordance with various embodiments of the present disclosure. For example, in FIG. 4, at least a clock signal (CLK), a trigger signal (TRIG), a power voltage signal (VP or V_{PDN}), a first sampling clock signal (SAMP), a sampled signal (S2), a second sampling clock signal (DoAcc), and an accumulated signal (AccOut) are shown. It should be understood that the scales of the signals are shown for illustrative purposes, and are not intended to limit the scope of the present disclosure.

As shown, the CLK signal is provided with a period T_{CLK} (i.e., a frequency of 1/T_{CLK}). In some embodiments, the impedance measurement circuit 300 may include a divider (not shown) configured to receive the CLK signal from a clock source and divide the frequency by N (i.e., f_{CLK}/N) or multiply the period by N (i.e., N×T_{CLK}) so as to provide it to as a global sampling clock signal (SCK signal) or the trigger signal (TRIG signal). The current source 310 and the delay circuit 360 can receive the SCK signal and the TRIG signal, respectively. The SCK signal and the TRIG signal can have the same frequency (f_{CLK}/N). With the repetitive on/off based on the frequency (f_{CLK}/N), the power voltage signal VP can also be provided (e.g., through a voltage controlled oscillator) with the same frequency (f_{CLK}/N). On the other hand, upon receiving the SCK signal, the delay circuit 360 can delay the SCK signal with a plural number of delay amounts (e.g., 1×LSB, 2×LSB, 3×LSB, etc., across the whole period N×T_{CLK}) as the SAMP signal.

In some embodiments, every time when the SAMP signal transitions from a low logic state to a high logic state (a rising edge), the edge sampler 330 can be activated to sample one data point on the power voltage signal VP as the S2 signal. Further, every time when the SAMP signal transitions from the same high logic state to a next low logic state (a falling edge immediately following the rising edge), the transition detector 350 can generate one of many pulses constituting the DoAcc signal. As such, the SAMP signal and the DoAcc signal, which function as the first sampling clock signal and the second sampling clock signal for the edge sampler 330 and the accumulator 340, respectively, can have the same frequency (f_{CLK}/N). By identifying a rising edge of the DoAcc signal, the accumulator 340 can be activated to accumulate the S2 signal as the AccOut signal, which may have the same frequency (f_{CLK}/N).

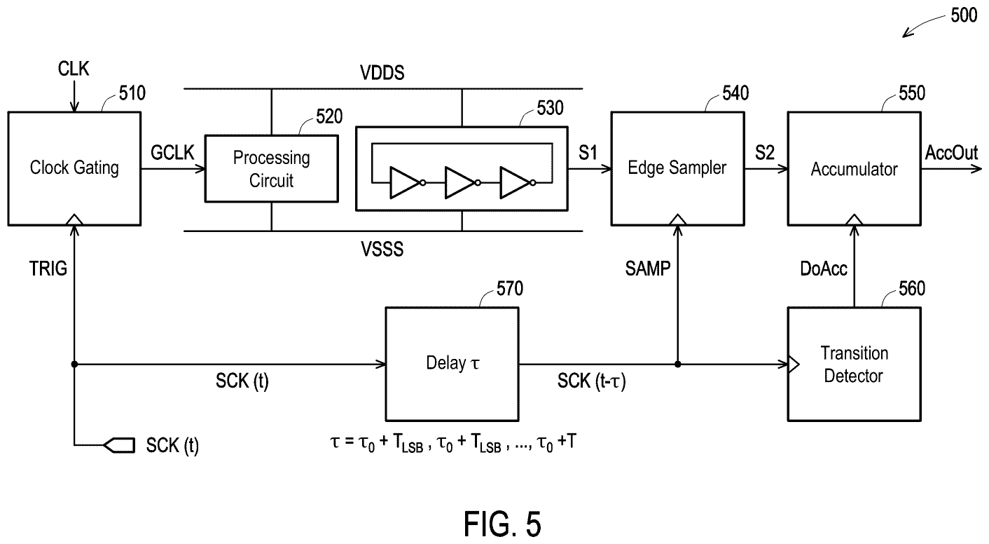

FIG. 5 illustrates another example circuit diagram of an impedance measurement circuit 500, in accordance with various embodiments of the present disclosure. The impedance measurement circuit 500 is substantially similar to the impedance measurement circuit 300, except that the impedance measurement circuit 500 is free from a current source. For example, the impedance measurement circuit 500 may be an alternative example implementation of the PIM BIST circuit 202. Accordingly, the following discussion of the impedance measurement circuit 500 will be focused on the difference.

As shown, the impedance measurement circuit 500 includes a gating circuit 510, a processing circuit 520, a voltage controlled oscillator (VCO) 530, an edge sampler 540, an accumulator 550, a transition detector 560, and a delay circuit 570. In some embodiments, the gating circuit 510 is configured to apply a gated clock signal (hereinafter “GCLK signal”) to the processing circuit 520 to adjust the power voltage signal VP (or the voltage difference between the internal power source VDDS and the internal power ground VSSS). In some embodiments, the processing circuit 520 may be implemented as a central processing unit (CPU), a graphic processing unit (GPU), a high-performance computing (HPC) device, or other suitable device. Other components (e.g., 530, 540, 550, 506, and 570) are substantially the same as the components described with respect to FIG. 3, and thus, the description is not repeated.

The gating circuit 510 is configured to generate the GCLK signal according to a clock signal (hereinafter “CLK signal”) and a global sampling clock signal (hereinafter “SCK signal”). The gating circuit 510 may be implemented as an isolation clock gating circuit. In various embodiments, the GCLK signal can be applied to various devices, such as devices and systems which need accurate start-up timing, devices which need to operate at a specific timing region, devices which need to be powered on or powered off for strict timing requirement without large uncertainty, and systems which need to start at a certain time point, such as a rocket launch system.

As a non-limiting example, the gating circuit 510 may include a D flip flop and an AND logic gate. A data input terminal of the flip flop can receive the SCK signal, a clock input terminal of the flip flop can receive the CLK signal, and an output terminal of the flip flop 210 can output an enable signal GN to be received by one of two input terminals of the AND logic gate. The other input terminal of the AND logic gate can receive the CLK signal. The flip flop can transmit a logic value of the SCK signal to its output terminal, when triggered (or activated) by an edge of the CLK signal, to generate the enable signal. The flip flop can invert a logic value and a corresponding voltage value of the CLK signal.

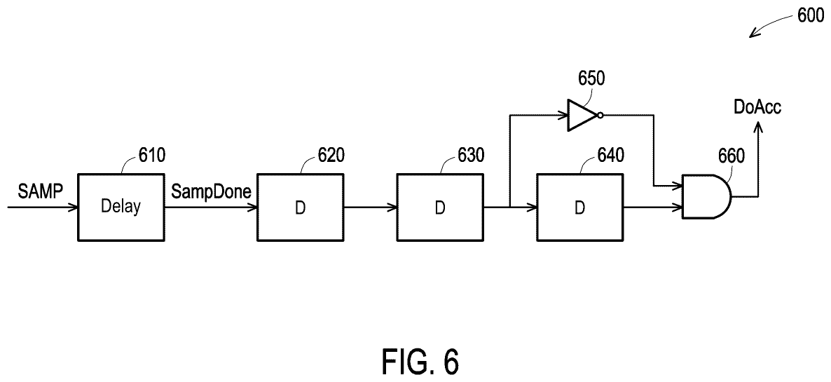

FIG. 6 illustrates an example circuit diagram of the disclosed transition detector (e.g., 350 of FIG. 3, 560 of FIG. 5), in accordance with various embodiments of the present disclosure. Hereinafter, the transition detector shown in FIG. 6 is referred to as “transition detector 600.” It should be understood that the circuit diagram of FIG. 6 has been simplified, and thus, the transition detector 600 can include any of various other components while remaining within the scope of the present disclosure.

As shown, the transition detector 600 includes a delay circuit 610, a number of D flip flops, 620, 630, and 640, an inverter 650, and an AND logic gate 660. In some embodiments, the delay circuit 610 may operatively form an analog side of the transition detector 600, while the rest of components may operatively form a digital side of the transition detector 600. The delay circuit 610 (on the analog side) is configured to receive a first sampling clock signal (e.g., the SAMP signal) from another delay circuit (e.g., 360 of FIG. 3, 570 of FIG. 5) and provide a SampDone signal to the digital side. Specifically, the flip flops 620 to 640 may be coupled to each other in series, with the inverter 650 connected to the last flip flop 640 in parallel. Further, the AND logic gate have a first input terminal configured to receive an output signal provided by the inverter 650, a second input terminal configured to receive an output signal provided by the last flip flop 640, and an output terminal configured to AND the two input signals to provide a second sampling clock signal (e.g., the DoAcc signal) for activating a corresponding accumulator (e.g., 340 of FIG. 3, 550 of FIG. 5).

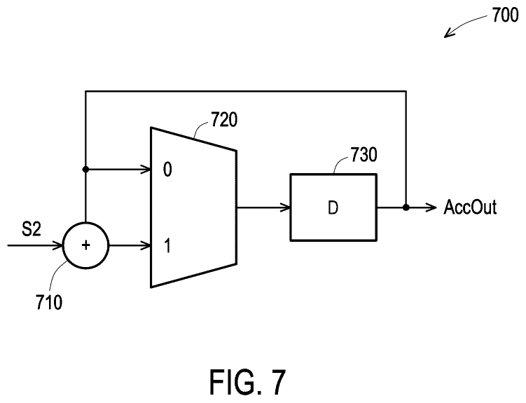

FIG. 7 illustrates an example circuit diagram of the disclosed accumulator (e.g., 340 of FIG. 3, 550 of FIG. 5), in accordance with various embodiments of the present disclosure. Hereinafter, the accumulator shown in FIG. 7 is referred to as “accumulator 700.” It should be understood that the circuit diagram of FIG. 7 has been simplified, and thus, the accumulator 700 can include any of various other components while remaining within the scope of the present disclosure.

As shown, the accumulator 700 includes an adder 710, a multiplexer 720, and a D flip flop 730. The adder 710 can receive a first input signal through one or more other D flip flops (e.g., the S2 signal) and a second input signal from an output of the accumulator 700 (e.g., the AccOut signal), and sum the first input signal and the second input signal. The multiplexer 720 can have a first input terminal configured to receive the AccOut signal, and a second input terminal configured to receive the summed signal outputted from the adder 710. Further, the multiplexer 720 can select one of the signals received from its first or second input terminal based on the second sampling clock signal (e.g., the DoAcc signal). For example, when the DoAcc signal is at a low logic state, the multiplexer 720 can select the DoAcc signal (i.e., maintaining the AccOut signal unchanged); and when the DoAcc signal is at a high logic state, the multiplexer 720 can select the summed signal (i.e., adding the DoAcc signal with the S2 signal).

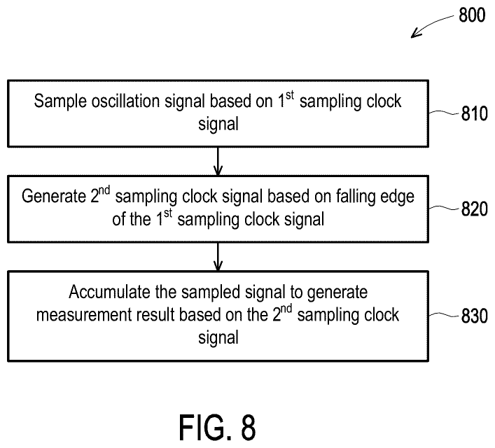

FIG. 8 illustrates a flow chart of an example method 800 for obtaining the profile of a PDN based on two sampling clock signals with the same frequency, in accordance with various embodiments of the present disclosure. Operations of the method 800 may be performed by the impedance measurement circuit described above (e.g., FIGS. 3-7), and thus, some of the reference numerals used above may be re-used the following discussion of the method 800. Further, it is understood that the method 800 has been simplified, and thus, additional operations may be provided before, during, and after the method 800 of FIG. 8, and that some other operations may only be briefly described herein.

The method 800 starts with operation 810 of sampling, based on a rising edge of a first sampling clock signal, an oscillation signal generated based on a voltage present on a power rail. The voltage (VP or V_{PDN}) on the power rail can be provided by a corresponding PDN, which can be a voltage difference across the power rail, e.g., VDDS−VSSS. The oscillation signal (e.g., the S1 signal) can be generated by a voltage controlled oscillator (e.g., 320 of FIG. 3, 530 of FIG. 5) that is controlled by the voltage VP. An edge sampler (330 of FIG. 3, 540 of FIG. 5), operatively coupled to the voltage controlled oscillator, can sample one data point on the S1 signal every time that the edge sampler identifies a rising edge of a first sampling clock signal (e.g., the SAMP signal), so as to generate a sampled signal (e.g., the S2 signal). In some embodiments, the first sampling clock signal can have a first frequency substantially similar to a frequency of a global sampling clock signal (e.g., the SCK signal) but with a delay amount.

The method 800 continues to operation 820 of generating, based on a falling edge of the first sampling clock signal, a second sampling clock signal. Continuing with the above example, a transition detector (350 of FIG. 3, 560 of FIG. 5) can receive the first sampling clock signal and identify a falling edge of the first sampling clock signal to generate a second sampling clock signal (e.g., the DoAcc signal). In some embodiments, immediately following the rising edge for sampling the S1 signal, the transition detector can generate a pulse for the second sampling clock signal. As such, the second sampling clock signal can have a second frequency that is substantially similar to the first frequency.

The method 800 continues to operation 830 of accumulating, based on the second sampling clock signal, the sampled signal to generate a measurement result. With the same example above, an accumulator (e.g., 340 of FIG. 3, 550 of FIG. 5), coupled to the edge sampler, can selectively accumulate the S2 signal based on the second sampling clock signal (the DoAcc signal), so as to generate a measurement result (e.g., the AccOut signal). In some embodiments, every time that the accumulator identifies a rising edge of the DoAcc signal, the accumulator can add the AccOut signal with the sampled S2 signal. Otherwise, the accumulator may keep the AccOut signal unchanged. Consequently, the disclosed impedance measurement circuit can construct a profile of the PDN according to a plural number of the measurement results.

In one aspect of the present disclosure, an impedance measurement circuit is disclosed. The impedance measurement circuit includes a voltage controlled oscillator (VCO) configured to generate an oscillation signal according to a power voltage present on a power rail. The impedance measurement circuit includes an edge sampler coupled to the VCO and configured to generate a first signal sampling the oscillation signal based on a first transition edge of a first sampling clock signal. The impedance measurement circuit includes an accumulator coupled to the edge sampler and configured to accumulate the first signal for generating a second signal based on a third transition edge of a second sampling clock signal. The impedance measurement circuit includes a transition detector configured to generate the second sampling clock signal based on detecting a second transition edge of the first sampling clock signal.

In another aspect of the present disclosure, an impedance measurement circuit is disclosed. The impedance measurement circuit includes a voltage controlled oscillator (VCO) configured to generate an oscillation signal according to a power voltage present on a power rail. The impedance measurement circuit includes an edge sampler coupled to the VCO and configured to sample the oscillation signal based on a rising edge of a first sampling clock signal. The impedance measurement circuit includes an accumulator coupled to the edge sampler and configured to accumulate the sampled signal for generating a measurement result based on a rising edge of a second sampling clock signal. The impedance measurement circuit includes a transition detector configured to generate the second sampling clock signal based on detecting a falling transition edge of the first sampling clock signal.

In yet another aspect of the present disclosure, a method for operating an impedance measurement circuit is disclosed. The method includes sampling, based on a rising edge of a first sampling clock signal, an oscillation signal generated based on a voltage present on a power rail. The method includes generating, based on a falling edge of the first sampling clock signal, a second sampling clock signal. The method includes accumulating, based on the second sampling clock signal, the sampled signal to generate a measurement result.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., ±10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An impedance measurement circuit, comprising:
a voltage controlled oscillator (VCO) configured to generate an oscillation signal according to a power voltage present on a power rail;
an edge sampler coupled to the VCO and configured to generate a first signal sampling the oscillation signal based on a first transition edge of a first sampling clock signal;
an accumulator coupled to the edge sampler and configured to accumulate the first signal for generating a second signal based on a third transition edge of a second sampling clock signal; and
a transition detector configured to generate the second sampling clock signal based on detecting a second transition edge of the first sampling clock signal.

2. The impedance measurement circuit of claim 1, wherein the first transition edge is a rising edge of the first sampling clock signal, the second transition edge is a falling edge of the first sampling clock signal, and the third transition edge is a rising edge of the second sampling clock signal.

3. The impedance measurement circuit of claim 1, wherein the first sampling clock signal is associated with a first frequency and the second sampling clock signal is associated with a second frequency, and wherein the first frequency is equal to the second frequency.

4. The impedance measurement circuit of claim 1, further comprising:
a current source coupled to the power rail and configured to sink a current from the power rail according to a third sampling clock signal; and
a delay circuit configured to delay the third sampling clock signal as the first sampling clock signal.

5. The impedance measurement circuit of claim 1, further comprising:
a clock gating circuit configured to generate a gated clock signal based on a third sampling clock signal;
a processing circuit coupled to the power rail and configured to sink a current from the power rail according to the gated clock signal; and
a delay circuit configured to delay the third sampling clock signal as the first sampling clock signal.

6. The impedance measurement circuit of claim 1, wherein the second transition edge is separated from the first transition edge by one half of a period of the first sampling clock signal.

7. The impedance measurement circuit of claim 1, wherein the third transition edge is separated from the second transition edge by a delay corresponding to the transition detector.

8. The impedance measurement circuit of claim 7, wherein the delay is about equal to a period of a clock signal, which is 1/N of a period of the first or second sampling clock signal.

9. The impedance measurement circuit of claim 1, wherein the transition detector includes:
an inverter having an input and an output;
a D flip flop having an input connected to the input of the invertor and an output connected to the output of the invertor; and
an AND logic gate having a first input connected to the output of the inverter, a second input connected to the output of the D flip flop, and an output configured to provide the second sampling clock signal.

10. The impedance measurement circuit of claim 1, wherein the accumulator includes:
an adder configured to receive the first signal and the second signal;
a multiplexer having a first input configured to receive an output signal of the adder, a second input configured to receive the second signal, and configured to provide an output signal as one of the output signal of the adder or the second signal based on the second sampling clock signal; and
a D flip flop configured to receive the output signal of the multiplexer and provide the second signal.

11. An impedance measurement circuit, comprising:
a voltage controlled oscillator (VCO) configured to generate an oscillation signal according to a power voltage present on a power rail;
an edge sampler coupled to the VCO and configured to sample the oscillation signal based on a rising edge of a first sampling clock signal;
an accumulator coupled to the edge sampler and configured to accumulate the sampled signal for generating a measurement result based on a rising edge of a second sampling clock signal; and
a transition detector configured to generate the second sampling clock signal based on detecting a falling transition edge of the first sampling clock signal.

12. The impedance measurement circuit of claim 11, wherein the falling transition edge of the first sampling clock signal immediately follows the rising transition edge of the first sampling clock signal, with a time difference equal to one half of a period of the first sampling clock signal.

13. The impedance measurement circuit of claim 11, wherein the first sampling clock signal is associated with a first frequency and the second sampling clock signal is associated with a second frequency, and wherein the first frequency is equal to the second frequency.

14. The impedance measurement circuit of claim 11, further comprising:
a current source coupled to the power rail and configured to sink a current from the power rail according to a third sampling clock signal; and
a delay circuit configured to delay the third sampling clock signal as the first sampling clock signal.

15. The impedance measurement circuit of claim 11, further comprising:
a clock gating circuit configured to generate a gated clock signal based on a third sampling clock signal;
a processing circuit coupled to the power rail and configured to sink a current from the power rail according to the gated clock signal; and
a delay circuit configured to delay the third sampling clock signal as the first sampling clock signal.

16. The impedance measurement circuit of claim 11, wherein the transition detector includes:
an inverter having an input and an output;
a D flip flop having an input connected to the input of the invertor and an output connected to the output of the invertor; and
an AND logic gate having a first input connected to the output of the inverter, a second input connected to the output of the D flip flop, and an output configured to provide the second sampling clock signal.

17. The impedance measurement circuit of claim 11, wherein the rising transition edge of the second sampling clock signal is separated from the falling transition edge of the first sampling clock signal by a delay corresponding to the transition detector.

18. A method, comprising:
sampling, based on a rising edge of a first sampling clock signal, an oscillation signal generated based on a voltage present on a power rail;
generating, based on a falling edge of the first sampling clock signal, a second sampling clock signal; and
accumulating, based on the second sampling clock signal, the sampled signal to generate a measurement result.

19. The method of claim 18, wherein the first sampling clock signal is associated with a first frequency and the second sampling clock signal is associated with a second frequency, and wherein the first frequency is equal to the second frequency.

20. The method of claim 18, wherein the falling transition edge of the first sampling clock signal immediately follows the rising transition edge of the first sampling clock signal, with a time difference equal to one half of a period of the first sampling clock signal.
